(19) United States
(12) Patent Application Publication
(10) Pub. No.: US 2025/0048907 A1
(43) Pub. Date: Feb. 6, 2025

(54) DISPLAY DEVICE

(71) Applicant: Samsung Display Co., Ltd., Yongin-Si (KR)

(72) Inventors: Ji Hye HAN, Yongin-si (KR); Chul Min BAE, Yongin-si, (KR); Soo Jin JUNG, Yongin-si (KR); Sug Woo JUNG, Yongin-si (KR)

(21) Appl. No.: 18/677,598

(22) Filed: May 29, 2024

(30) Foreign Application Priority Data
Jul. 31, 2023 (KR) 10-2023-0099318

(51) Int. Cl. H10K 59/80; G02B 27/01; H10K 59/122; H10K 59/131; H10K 59/35

(52) U.S. Cl. CPC H10K 59/8794; H10K 59/122; H10K 59/131; H10K 59/353; G02B 27/0172; G02B 2027/0178

(57) ABSTRACT

A display device is provided. The display device may include a substrate, a driving element layer on the substrate, and a light emitting element layer on the driving element layer. The light emitting element layer may include a pixel defining layer delimiting sub-pixels, a first electrode of each sub-pixel in an opening of the pixel defining layer, a heating line disposed on the pixel defining layer to surround the first electrode of each sub-pixel, an intermediate layer covering the first electrode in the opening and the pixel defining layer and being partially disconnected above the heating line, and a second electrode continuously covering the intermediate layer and the heating line between adjacent sub-pixels while covering the intermediate layer in the opening. The heating line surrounds a pair of first electrodes corresponding to the adjacent sub-pixels in a form of a Eulerian trail.

### CROSS-REFERENCE TO RELATED APPLICATION

This application claims priority from Korean Patent Application No. 10-2023-0099318 filed on Jul. 31, 2023, in the Korean Intellectual Property Office, and all the benefits accruing therefrom under 35 U.S.C. 119, the contents of which in its entirety are herein incorporated by reference.

### BACKGROUND

### Technical Field

The present disclosure relates to a display device.

### Description of the Related Art

Wearable devices have been developed that form a focus close to a user's eyes. For example, a wearable device may take the form of glasses or a helmet that may be a head mounted display (HMD) device. The wearable device may provide to a user an augmented reality (hereinafter, referred to as “AR”) screen or a virtual reality (hereinafter, referred to as “VR”) screen.

A wearable device such as an HMD device or AR glasses may require a display specification of at least 2000 PPI (pixels per inch) to avoid making a user dizzy after extended use of the wearable device. To this end, organic light emitting diode on silicon (OLEDoS) technology that provides a high-resolution small organic light emitting display device is emerging. The organic light emitting diode on silicon (OLEDoS) technology may provide an organic light emitting diode (OLED) on a semiconductor wafer substrate in or on which complementary metal oxide semiconductor (CMOS) devices may be fabricated.

A display panel to which the OLEDoS technology is applied may encounter unintended leakage current between adjacent pixels when the distance between the adjacent pixels is small. The leakage current may be through conductive layers among intermediate layers disposed between a pixel electrode (for example, an anode electrode of an OLED) and a common electrode (for example, a cathode electrode of an OLED), and is known to be a cause of color crosstalk between adjacent pixels.

### SUMMARY

Embodiments of the present disclosure provide a display device for preventing leakage current and color crosstalk by disconnecting at least a part of an intermediate layer, which is disposed between a pixel electrode and a common electrode, between adjacent pixels.

According to an embodiment of the present disclosure, a display device may include a substrate, a driving element layer disposed on the substrate, and a light emitting element layer disposed on the driving element layer. The light emitting element layer may include a pixel defining layer configured to delimit a plurality of sub-pixels, a first electrode of each sub-pixel disposed in an opening of the pixel defining layer, a heating line disposed on the pixel defining layer to surround the first electrode of each sub-pixel, an intermediate layer configured to cover the first electrode in the opening and cover the pixel defining layer, and configured to be partially disconnected above the heating line, and a second electrode disposed continuously to cover the intermediate layer and the heating line between adjacent sub-pixels while covering the intermediate layer in the opening. The heating line is disposed to surround a pair of first electrodes corresponding to the adjacent sub-pixels in a form of a Eulerian trail.

A wiring layer including a power line and a ground line is disposed between the driving element layer and the light emitting element layer, and the power line and the ground line are disposed to cross between sub-pixels disposed in an odd row and sub-pixels disposed in an even row. The light emitting element layer further may include a first connection electrode configured to connect a start point of the heating line to the power line through a first contact hole penetrating the pixel defining layer and at least a part of the wiring layer, and a second connection electrode configured to connect an end point of the heating line to the ground line through a second contact hole penetrating the pixel defining layer and at least a part of the wiring layer.

The start point and the end point of the heating line are located between the sub-pixels disposed in the odd row and the sub-pixels disposed in the even row.

The heating line extends from the start point to surround a second reference sub-pixel among the sub-pixels disposed in the even row, and is connected to a midpoint adjacent to the start point, and the heating line extends from the midpoint to surround a first reference sub-pixel adjacent to the second reference sub-pixel among the sub-pixels disposed in the odd row, and is connected to the end point.

The midpoint of the heating line is disposed between the start point and the end point.

When viewed in a normal direction of the substrate, the heating line has a shape of alphabet “S” as it extends from the start point to the end point via the midpoint.

The first electrode of each sub-pixel has an n-gonal shape (n is an integer greater than or equal to 4) when viewed in the normal direction of the substrate, and the heating line has an n-gonal shape spaced apart from the first electrode at a specific interval when viewed in the normal direction of the substrate.

The first electrode of each sub-pixel has a hexagonal shape when viewed in the normal direction of the substrate, and the heating line has the hexagonal shape spaced apart from the first electrode at a specific interval when viewed in the normal direction of the substrate.

The power line is connected to a power pad disposed in a non-display area of the substrate, and the power pad may include a main pad to which a Joule heating voltage is applied, and sub-pads branched from the main pad and provided for each group obtained by evenly dividing a plurality of power lines. The power lines comprised in each group receive the Joule heating voltage through the sub-pad.

The power line is connected to a power pad disposed in a non-display area of the substrate, the power pad may include group pads to which a Joule heating voltage is applied, and provided for each group obtained by evenly dividing a plurality of power lines, and the power lines comprised in each group receive the Joule heating voltage through the group pad.

According to an embodiment of the present disclosure, a display device may include a substrate, a driving element layer disposed on the substrate, and a light emitting element layer disposed on the driving element layer. The light emitting element layer may include a pixel defining layer configured to delimit a plurality of sub-pixels, a first electrode of each sub-pixel disposed in an opening of the pixel defining layer, a heating line disposed on the pixel defining layer to surround the opening of each sub-pixel, an intermediate layer configured to cover the first electrode in the opening and cover the pixel defining layer, and configured to be partially disconnected above the heating line, and a second electrode disposed continuously to cover the intermediate layer and the heating line between adjacent sub-pixels while covering the intermediate layer in the opening. The heating line is disposed to surround a pair of openings corresponding to the adjacent sub-pixels in a form of a Eulerian trail.

A wiring layer including a power line and a ground line is disposed between the driving element layer and the light emitting element layer, and the power line and the ground line are disposed to cross between sub-pixels disposed in an odd row and sub-pixels disposed in an even row. The light emitting element layer further may include a first connection electrode configured to connect a start point of the heating line to the power line through a first contact hole penetrating the pixel defining layer and at least a part of the wiring layer, and a second connection electrode configured to connect an end point of the heating line to the ground line through a second contact hole penetrating the pixel defining layer and at least a part of the wiring layer.

One pixel may include a first emission area of a first sub-pixel displaying red light, a second emission area of a second sub-pixel displaying green light, and a third emission area of a third sub-pixel displaying blue light, the first emission area and the second emission area are disposed adjacent to each other in a column direction, the first emission area and the third emission area are disposed adjacent to each other in a row direction, and a third length of the third emission area in the column direction is greater than or equal to a sum of a first length of the first emission area in the column direction and a second length of the second emission area in the column direction.

The heating line may include a first heating line disposed to surround the first emission area and the second emission area in the form of the Eulerian trail, and a second heating line disposed to surround the third emission area.

A first start point and a first end point of the first heating line are disposed between the second emission area of the pixel disposed in the odd row and the first emission area of the pixel disposed in the even row, and a second start point and a second end point of the second heating line are disposed between the third emission area of the pixel disposed in the odd row and the third emission area of the pixel disposed in the even row.

The first heating line extends from the first start point to a midpoint between the first emission area and the second emission area and extends from the midpoint to the first end point while surrounding a periphery of the second emission area.

The midpoint is disposed in a vicinity of a corner of the first emission area adjacent to the third emission area.

Each of the first to third emission areas has a rectangular shape in plan view.

The power line is connected to a power pad disposed in a non-display area of the substrate, and the power pad may include a main pad to which a Joule heating voltage is applied, and sub-pads branched from the main pad and provided for each group obtained by evenly dividing a plurality of power lines. The power lines comprised in each group receive the Joule heating voltage through the sub-pad.

The power line is connected to a power pad disposed in a non-display area of the substrate, the power pad may include group pads to which a Joule heating voltage is applied, and provided for each group obtained by evenly dividing a plurality of power lines, and the power lines comprised in each group receive the Joule heating voltage through the group pad.

In accordance with the display device according to embodiments, the leakage current and the color crosstalk may be prevented by disconnecting at least a part of the intermediate layer, which is disposed between the pixel electrode and the common electrode, between adjacent pixels.

However, aspects of the present disclosure are not restricted to those set forth herein. The above and other aspects of the present disclosure will become more apparent to one of ordinary skill in the art to which the present disclosure pertains by referencing the detailed description given below.

### BRIEF DESCRIPTION OF THE DRAWINGS

The above and other aspects and features of the present disclosure will become more apparent by describing in detail example embodiments with reference to the attached drawings.

FIG. 1 is a perspective view illustrating a head mounted display device according to one embodiment.

FIG. 2 is an exploded perspective view illustrating an example of the head mounted display device of FIG. 1.

FIG. 3 is a perspective view illustrating a head mounted display device according to one embodiment.

FIG. 4 is an exploded perspective view showing a display device according to one embodiment.

FIG. 5 is a layout diagram illustrating an example of the display panel shown in FIG. 4.

FIG. 6 is a block diagram illustrating a display device according to one embodiment.

FIG. 7 is an equivalent circuit diagram of a first sub-pixel according to one embodiment.

FIG. 8 schematically illustrates a cross section of a portion of a display panel according to one embodiment.

FIG. 9 shows a power line disposed on the same layer as a reflective electrode according to one embodiment.

FIG. 10 shows a power line in a wiring layer according to one embodiment.

FIG. 11 shows a power line in a buffer layer according to one embodiment.

FIG. 12 is a plan view of heating lines according to one embodiment.

FIG. 13 is a plan view illustrating heating lines with a hexagonal shape.

FIG. 14 is a plan view showing a power pad according to one embodiment.

FIG. 15 is a plan view illustrating another shape of the power pad according to one embodiment.

FIG. 16 is a plan view illustrating heating lines according to one embodiment.

FIG. 17 is a flowchart illustrating a manufacturing method of a display panel according to one embodiment.

FIGS. 18, 19, 20, and 21 are cross-sectional views sequentially illustrating the manufacturing method of the display panel according to one embodiment.

### DETAILED DESCRIPTION OF THE EMBODIMENTS

Some specific embodiments in accordance with the present disclosure are described more fully hereinafter with reference to the accompanying drawings. This disclosure should not be construed as being limited to the specific embodiments set forth herein. Rather, these embodiments are provided so that this disclosure will be thorough and complete and will fully convey an understanding to those skilled in the art.

It will also be understood that when a layer is referred to as being “on” another layer or substrate, the layer can be directly on the other layer or substrate, or one or more intervening layers may also be present.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the present disclosure. Similarly, the second element could also be termed the first element.

Features of each of various embodiments of the present disclosure may be partially or entirely combined with each other and may variously interwork with each other, and respective embodiments may be implemented independently of each other or may be implemented together in association with each other.

Hereinafter, specific embodiments will be described with reference to the accompanying drawings. Features and components in the drawings may not be shown to scale and may be altered in shape or exaggerated or reduced in size for clarity of illustration or explanation. Use of the same reference numbers throughout the drawings and the specification indicates the same or corresponding components.

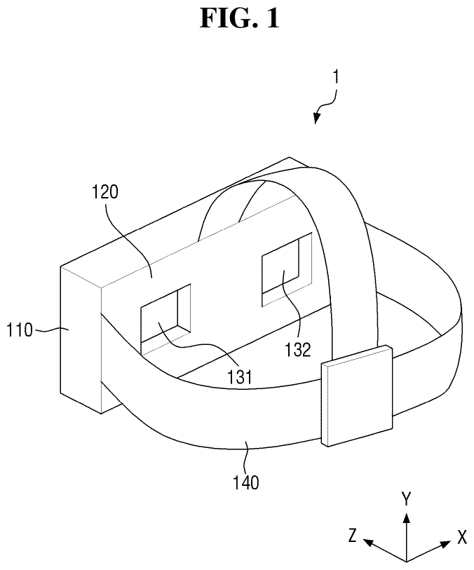

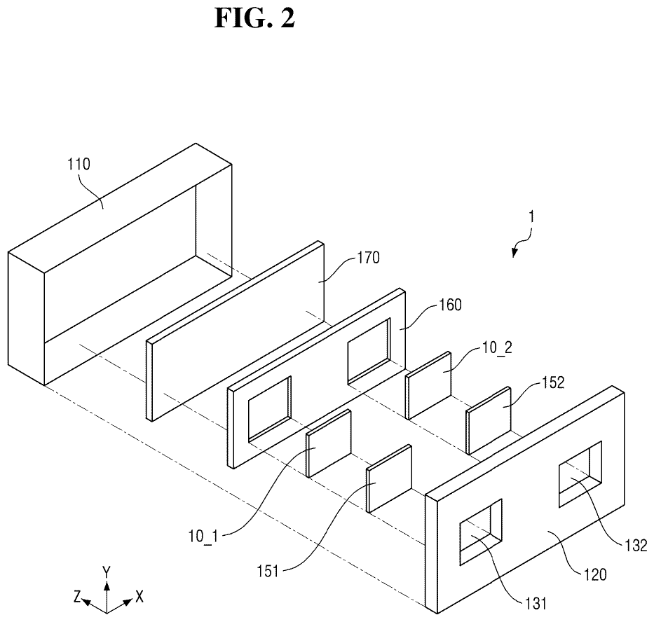

FIG. 1 is a perspective view illustrating a head mounted display device according to one embodiment. FIG. 2 is an exploded perspective view illustrating an example of the head mounted display device of FIG. 1.

Referring to FIGS. 1 and 2, a head mounted display device 1 according to one embodiment includes a first display device 10_1, a second display device 10_2, a display device housing 110, a housing cover 120, a first eyepiece 131, a second eyepiece 132, a head mounted band 140, a middle frame 160, a first optical member 151, a second optical member 152, a control circuit board 170, and a connector.

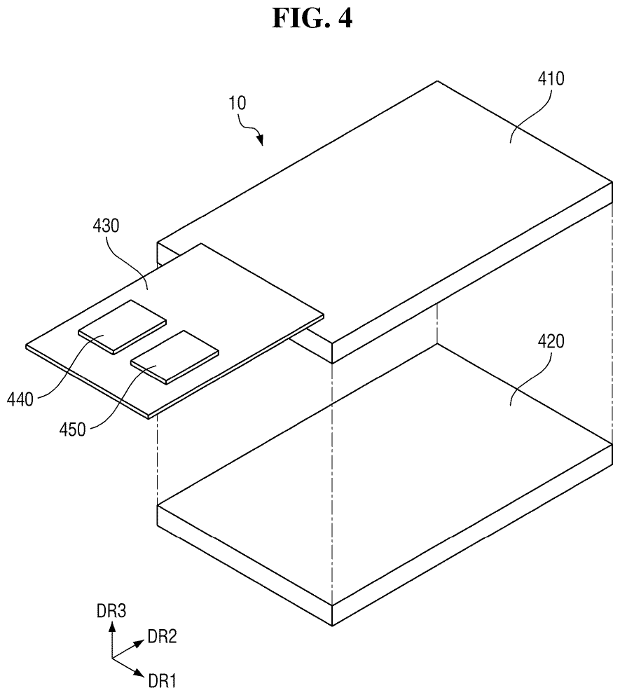

The first display device 10_1 provides an image to the user's left eye, and the second display device 10_2 provides an image to the user's right eye. Each of the first display device 10_1 and the second display device 10_2 is substantially the same as the display device 10 described with reference to FIGS. 4 to 21. Therefore, the description of the first display device 10_1 and the second display device 10_2 will be replaced with the description with reference to FIGS. 4 to 21.

The first optical member 151 may be disposed between the first display device 10_1 and the first eyepiece 131. The second optical member 152 may be disposed between the second display device 10_2 and the second eyepiece 132. Each of the first optical member 151 and the second optical member 152 may include at least one convex lens.

The middle frame 160 may be disposed between the first display device 10_1 and the control circuit board 170 and may be disposed between the second display device 10_2 and the control circuit board 170. The middle frame 160 may support and fix the first display device 10_1, the second display device 10_2, and the control circuit board 170.

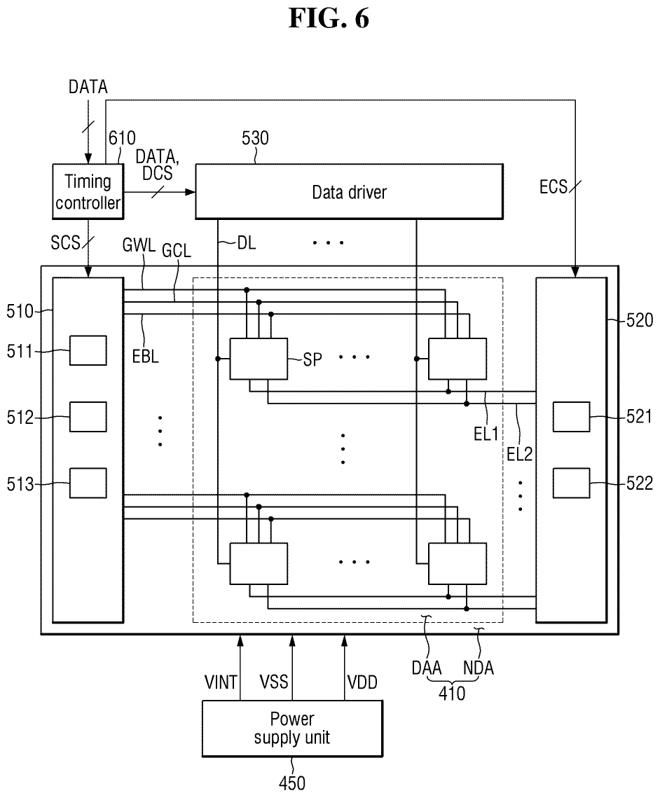

The control circuit board 170 may be disposed between the middle frame 160 and the display device housing 110. The control circuit board 170 may be connected to the first display device 10_1 and the second display device 10_2 through the connector. The control circuit board 170 may receive an image source from outside the head mounted display device 1, convert the image source into digital video data DATA (see FIG. 6), and transmit the digital video data DATA to the first display device 10_1 and the second display device 10_2 through the connector.

The control circuit board 170 may transmit the digital video data DATA corresponding to a left eye image optimized for a user's left eye to the first display device 10_1 and may transmit the digital video data DATA corresponding to a right eye image optimized for a user's right eye to the second display device 10_2. Alternatively, the control circuit board 170 may transmit the same digital video data DATA to the first display device 10_1 and the second display device 10_2.

The display device housing 110 may store the first display device 10_1, the second display device 10_2, the middle frame 160, the first optical member 151, the second optical member 152, the control circuit board 170, and the connector. The housing cover 120 may cover an open side of the display device housing 110. The housing cover 120 may include the first eyepiece 131 positioned for the user's left eye and the second eyepiece 132 positioned for the user's right eye. Although FIGS. 1 and 2 show that the first eyepiece 131 and the second eyepiece 132 are separate, the present disclosure is not limited thereto. The first eyepiece 131 and the second eyepiece 132 may be integrated into one piece.

The first eyepiece 131 may be aligned with the first display device 10_1 and the first optical member 151, and the second eyepiece 132 may be aligned with the second display device 10_2 and the second optical member 152. Therefore, a left eye of a user may view the image of the first display device 10_1 magnified as a virtual image by the first optical member 151 through the first eyepiece 131, and a right eye of the user may view the image of the second display device 10_2 magnified as a virtual image by the second optical member 152 through the second eyepiece 132.

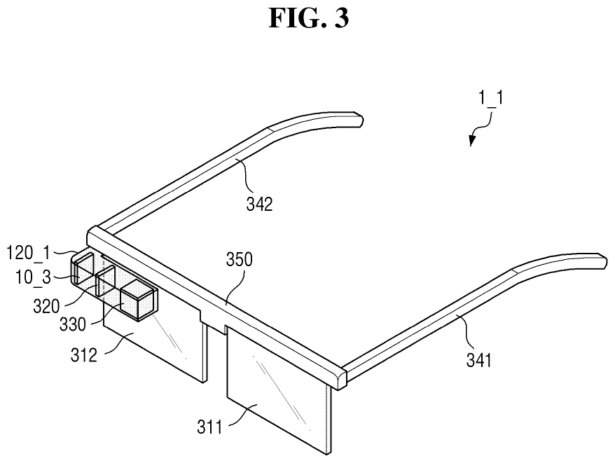

The head mounted band 140 may fix the display device housing 110 to a user's head in a position so that the first eyepiece 131 and the second eyepiece 132 of the housing cover 120 are adjacent to a user's left eye and the user's right eye, respectively. When the display device housing 110 is implemented as a light and small device, the head mounted band 140 may not be required, and the head mounted display device 1 may instead include an eyeglass frame such as shown in FIG. 3.

The head mounted display device 1 may further include a battery for supplying a power, an external memory slot capable of storing an external memory, an external connection port for receiving an image source, and a wireless communication module. The external connection port may be a universe serial bus (USB) connector, a display port, or a high-definition multimedia interface (HDMI) connector, and the wireless communication module may be a 5G communication module, a 4G communication module, a Wi-Fi module, or a Bluetooth module.

FIG. 3 is a perspective view illustrating a head mounted display device according to one embodiment.

Referring to FIG. 3, a head mounted display device 1_1 according to one embodiment may be a glasses-type display device in which a display device housing 1201 is implemented as a light weight and small device. The head mounted display device 1_1 according to one embodiment may include a display device 10_3, a left lens 311, a right lens 312, a support frame 350, temples 341 and 342, an optical member 320, an optical path changing member 330, and the display device housing 1201.

The display device 10_3 shown in FIG. 3 may be substantially the same as the display device 10 described below with reference to FIGS. 4 to 21. Therefore, detailed description of some specific embodiments of the display device 10_3 is provided below in the description with reference to FIGS. 4 to 21.

The display device housing 1201 may contain the display device 10_3, the optical member 320, and the optical path changing member 330. The image displayed on the display device 10_3 may be magnified by the optical member 320, may be viewable along an optical path changed by the optical path changing member 330, and may be provided to a user's right eye through the right lens 312. Accordingly, the right eye of the user may view an augmented reality image in which a virtual image displayed on the display device 10_3 and a real image seen through the right lens 312 are combined.

Although FIG. 3 illustrates the display device housing 120_1 at the right end of the support frame 350, embodiments of the present disclosure are not limited thereto. For example, the display device housing 1201 may be disposed at the left end of the support frame 350, in which case, the image of the display device 10_3 may be provided to the user's left eye. Alternatively, the display device housing 120_1 may be disposed at both the left end and the right end of the support frame 350, in which case, the user may view the image displayed on the display device 10_3 through both the left eye and the right eye.

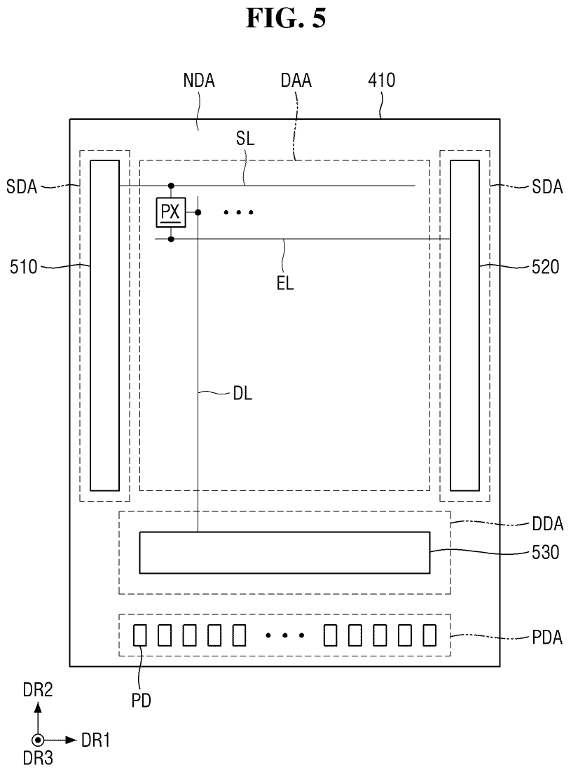

FIG. 4 is an exploded perspective view showing a display device according to one embodiment. FIG. 5 is a layout diagram illustrating an example of the display panel shown in FIG. 4. FIG. 6 is a block diagram illustrating a display device according to one embodiment.

Referring to FIGS. 4 and 5, a display device 10 according to one embodiment is a device capable of displaying a moving image or a still image. The display device 10 according to one embodiment may be applied to portable electronic devices such as a mobile phone, a smartphone, a tablet personal computer, a mobile communication terminal, an electronic organizer, an electronic book, a portable multimedia player (PMP), a navigation system, an ultra mobile PC (UMPC) or the like. For example, the display device 10 may be applied as a display unit of a television, a laptop, a monitor, a billboard, or an Internet-of-Things (IoT) device. Alternatively, the display device 10 may be applied to a smart watch, a watch phone, and a head mounted display (HMD) for realizing virtual reality or augmented reality.

The display device 10 according to one embodiment includes a display panel 410, a heat dissipation layer 420, a circuit board 430, a driving circuit 440, and a power supply circuit 450.

The display panel 410 may have a planar shape similar to a quadrilateral shape. For example, the display panel 410 may have a planar shape similar to a quadrilateral shape having short sides extending in a first direction DR1 and long sides extending in a second direction DR2 at an angle with the first direction DR1. In the display panel 410, a corner where a short side in the first direction DR1 and a long side in the second direction DR2 may meet at a right angled or may be rounded with a predetermined curvature. The planar shape of the display panel 410 is not limited to a rectangular shape and may be a shape similar to another polygonal shape, a circular shape, or an elliptical shape. The planar shape of the display device 10 may follow the planar shape of the display panel 410, but embodiments of the present disclosure are not limited thereto.

The display panel 410 includes a display area DAA and a non-display area NDA as shown in FIG. 5. The display area DAA is for displaying an image, and the non-display area NDA does not display an image.

The display area DAA includes a plurality of pixels PX or subpixels SP, a plurality of scan lines SL, a plurality of emission control lines EL, and a plurality of data lines DL.

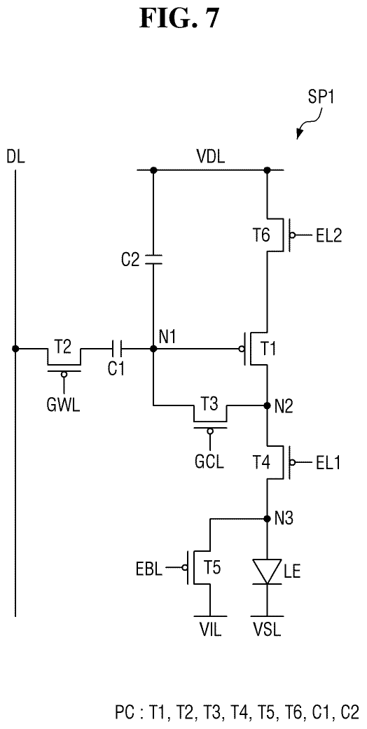

Each of the pixels PX or sub-pixels SP may include a light emitting element LE emitting light such as shown in FIG. 7. The plurality of pixels PX may be arranged in a matrix or array form with rows extending in the first direction DR1 and columns extending in the second direction DR2. The plurality of scan lines SL and the plurality of emission control lines EL may extend in the first direction DR1, while being arranged or spaced along the second direction DR2. The plurality of data lines DL may extend in the second direction DR2 and may be arranged or spaced along the first direction DR1.

The plurality of scan lines SL may include a plurality of write scan lines GWL, a plurality of control scan lines GCL, and a plurality of bias scan lines EBL as shown in FIG. 6. The plurality of emission control lines EL may include a plurality of first emission control lines EL1 and a plurality of second emission control lines EL2.

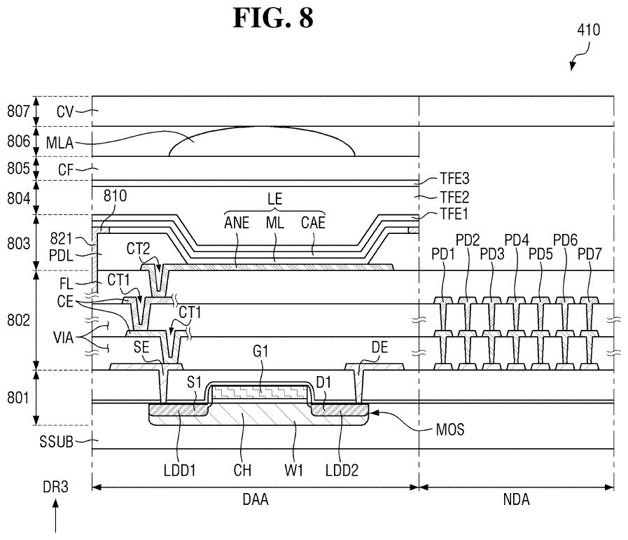

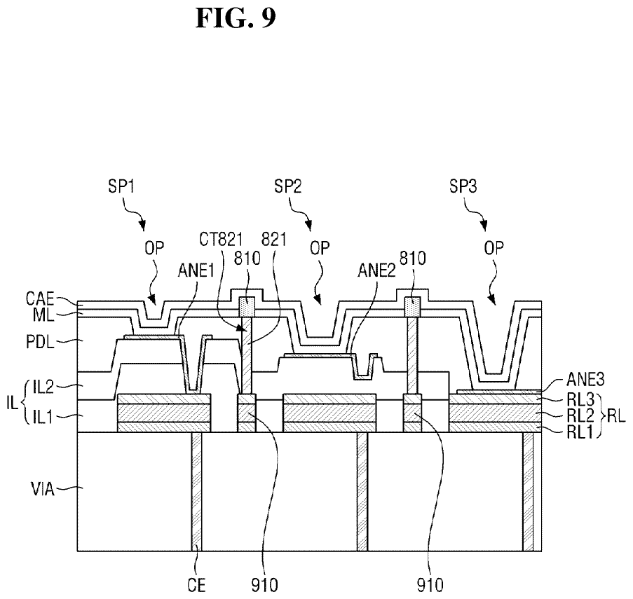

Each of the plurality of pixels PX may include a plurality of sub-pixels SP1, SP2, and SP3 (see FIG. 9). Each of the sub-pixels SP1, SP2, and SP3 may include a plurality of pixel transistors as shown in FIG. 7, and the plurality of pixel transistors may be formed by a semiconductor process and disposed on a semiconductor substrate SSUB (see FIG. 8). For example, the plurality of pixel transistors may be formed as complementary metal oxide semiconductor (CMOS) devices.

Each of the plurality of sub-pixels SP1, SP2, and SP3 may be connected to one write scan line GWL among the plurality of write scan lines GWL, one control scan line GCL among the plurality of control scan lines GCL, one bias scan line EBL among the plurality of bias scan lines EBL, one first light emission control line EL1 among the plurality of first light emission control lines EL1, one second emission control line EL2 among the plurality of second emission control lines EL2, and one data line DL among the plurality of data lines DL. Each of the plurality of sub-pixels SP1, SP2, and SP3 may receive a data voltage from a connected one of the data line DL in response to a write scan signal of the connected write scan line GWL and may emit light from its light emitting element LE according to the data voltage.

The non-display area NDA includes a scan driving area SDA, a data driving area DDA, and a pad area PDA as shown in FIG. 5.

The scan driving area SDA may be an area where a scan driver 510 and an emission driver 520 are disposed. Although FIG. 5 shows the scan driver 510 on the left side of the display area DAA and the emission driver 520 on the right side of the display area DAA, embodiments of the present disclosure are not limited thereto. For example, the scan driver 510 and the emission driver 520 may both be on the left side and/or the right side of the display area DAA.

The scan driver 510 includes a plurality of scan transistors, and the emission driver 520 includes a plurality of emission control transistors. The plurality of scan transistors and the plurality of emission control transistors may be formed by a semiconductor process and may be formed on the semiconductor substrate SSUB (see FIG. 8). For example, the plurality of scan transistors and the plurality of emission control transistors may be CMOS devices.

The scan driver 510 may include a write scan signal output unit 511, a control scan signal output unit 512, and a bias scan signal output unit 513 as shown in FIG. 6. Each of the write scan signal output unit 511, the control scan signal output unit 512, and the bias scan signal output unit 513 may receive a scan timing control signal SCS from a timing controller 610. The write scan signal output unit 511 may generate write scan signals in response to the scan timing control signal SCS from the timing controller 610 and sequentially output the write scan signals to the write scan lines GWL. The control scan signal output unit 512 may generate control scan signals in response to the scan timing control signal SCS and sequentially output the control scan signals to the control scan lines GCL. The bias scan signal output unit 513 may generate bias scan signals in response to the scan timing control signal SCS and sequentially output the bias scan signals to the bias scan lines EBL.

The emission driver 520 includes a first emission control driver 521 and a second emission control driver 522. Each of the first emission control driver 521 and the second emission control driver 522 may receive an emission timing control signal ECS from the timing controller 610. The first emission control driver 521 may generate first emission control signals in response to the emission timing control signal ECS and sequentially output the first emission control signals to the first emission control lines EL1. The second emission control driver 522 may generate second emission control signals in response to the emission timing control signal ECS and sequentially output the second emission control signals to the second emission control lines EL2.

The data driving area DDA may be an area where a data driver 530 is disposed. The data driver 530 may include a plurality of data transistors, and the plurality of data transistors may be formed by a semiconductor process and may be formed on the semiconductor substrate SSUB (see FIG. 8). For example, the plurality of data transistors may be CMOS devices.

The data driver 530 may receive the digital video data DATA and the data timing control signal DCS from the timing controller 610. The data driver 530 may convert the digital video data DATA into analog data voltages in response to the data timing control signal DCS and may output the analog data voltages to the data lines DL. In an embodiment having three sub-pixels SP1, SP2, and SP3 per pixel, the sub-pixels SP1, SP2, and SP3 are selected by the write scan signal of the scan driver 510, and data voltages may be supplied to the selected sub-pixels SP1, SP2, and SP3.

The pad area PDA includes a plurality of pads PD, which may be linearly distributed along the first direction DR1. Each of the plurality of pads PD may be exposed without being covered by a cover member CV (see FIG. 8) and a polarizing plate.

The heat dissipation layer 420 may overlap the display panel 410 in the third direction DR3, which is the thickness direction of the display panel 410 as shown in FIG. 4. The heat dissipation layer 420 may be disposed on one surface, for example, the rear surface of the display panel 410. The heat dissipation layer 420 serves to dissipate heat that the display panel 410 generates. The heat dissipation layer 420 may include a layer of metal or other high thermal conductivity material, such as graphite, silver (Ag), copper (Cu), or aluminum (Al).

The circuit board 430 may be electrically connected to the plurality of pads PD in the pad area PDA of the display panel 410 by using a conductive adhesive member such as an anisotropic conductive film. The circuit board 430 may be a flexible printed circuit board containing a flexible material or a flexible film. Although FIG. 4 shows the circuit board 430 unfolded or flat, the circuit board 430 may be bent. For example, one end of the circuit board 430 may be on or adjacent to the rear surface of the display panel 410. The end of the circuit board 430 bent behind the display panel 410 may be opposite from the end of the circuit board 430 connected to the plurality of pads PD of the pad area PDA of the display panel 410 by a conductive adhesive member.

The timing controller 610 may receive digital video data DATA and timing signals from the outside the display device 10. The timing controller 610 may generate the scan timing control signal SCS, the emission timing control signal ECS, and the data timing control signal DCS for controlling the display panel 410 in response to the timing signals. The timing controller 610 may output the scan timing control signal SCS to the scan driver 510 and output the emission timing control signal ECS to the emission driver 520. The timing controller 610 may output the digital video data DATA and the data timing control signal DCS to the data driver 530.

The power supply circuit 450 may generate a plurality of panel driving voltages in response to a power voltage from the outside the display device 10. For example, the power supply circuit 450 may generate and supply a first driving voltage VSS, a second driving voltage VDD, and a third driving voltage VINT to the display panel 410. The first driving voltage VSS, the second driving voltage VDD, and the third driving voltage VINT are described further below with reference to FIG. 7.

Each of the timing controller 610 and the power supply circuit 450 may be formed as an integrated circuit (IC) and attached to one surface of the circuit board 430. The scan timing control signal SCS, the emission timing control signal ECS, the digital video data DATA, and the data timing control signal DCS from the timing controller 610 may be supplied to the display panel 410 through the circuit board 430. The first driving voltage VSS, the second driving voltage VDD, and the third driving voltage VINT from the power supply circuit 450 may be supplied to the display panel 410 through the circuit board 430.

FIG. 7 is an equivalent circuit diagram of a sub-pixel according to one embodiment. The equivalent circuit diagram may apply to any sub-pixel SP1, SP2, or SP3 (see FIG. 9), but FIG. 7 shows a first sub-pixel SP1 to provide one specific example.

Referring to FIG. 7, the first sub-pixel SP1 may be connected to the write scan line GWL, the control scan line GCL, the bias scan line EBL, the first emission control line EL1, the second emission control line EL2, and the data line DL, which are associated with the first sub-pixel SP1. Further, the first sub-pixel SP1 may be connected to a first driving voltage line VSL to which the first driving voltage VSS (see FIG. 6) corresponding to a low potential voltage is applied, a second driving voltage line VDL to which the second driving voltage VDD (see FIG. 6) corresponding to a high potential voltage is applied, and a third driving voltage line VIL to which the third driving voltage VINT (see FIG. 6) corresponding to an initialization voltage is applied. That is, the first driving voltage line VSL may be a low potential voltage line, the second driving voltage line VDL may be a high potential voltage line, and the third driving voltage line VIL may be an initialization voltage line. In this case, the first driving voltage VSS may be a voltage lower than the third driving voltage VINT. The second driving voltage VDD may be higher than the third driving voltage VINT.

The first sub-pixel SP1 includes the light emitting element LE and a pixel driving circuit PC connected to the light emitting element LE. The pixel driving circuit PC includes a plurality of transistors T1 to T6, a first capacitor C1, and a second capacitor C2.

The light emitting element LE emits light in response to a driving current flowing through the channel of the first transistor T1. The emission amount of the light emitting element LE may be proportional to the driving current. The light emitting element LE may be an organic light emitting diode including a first electrode, a second electrode, and an organic light emitting layer disposed between the first electrode and the second electrode, but embodiments of the present disclosure are not limited thereto. For example, the light emitting element LE may be an inorganic light emitting element including a first electrode, a second electrode, and an inorganic semiconductor disposed between the first electrode and the second electrode and, in this case, the light emitting element LE may be a micro light emitting diode. The light emitting element LE may be disposed between the fourth transistor T4 and the first driving voltage line VSL. The first electrode of the light emitting element LE may be connected to the drain electrode of the fourth transistor T4, and the second electrode may be connected to the first driving voltage line VSL. The first electrode of the light emitting element LE may be an anode electrode (or pixel electrode), and the second electrode of the light emitting element LE may be a cathode electrode (or common electrode).

The first transistor T1 may be a driving transistor that controls the source-drain current (hereinafter, referred to as “driving current”) flowing between a source electrode and a drain electrode in response to the voltage applied to a gate electrode. The first transistor T1 has a gate electrode connected to a first node N1, a source electrode connected to a drain electrode of the sixth transistor T6, and a drain electrode connected to a second node N2.

The second transistor T2 may be disposed between the data line DL and one electrode of the first capacitor C1. The second transistor T2 is turned on by the write scan signal of the write scan line GWL to connect one electrode of the first capacitor C1 to the data line DL. Accordingly, the data voltage of the data line DL may be applied to one electrode of the first capacitor C1. The second transistor T2 includes a gate electrode connected to the write scan line GWL, a source electrode connected to the data line DL, and a drain electrode connected to one electrode of the first capacitor C1.

The third transistor T3 may be disposed between the first node N1 and the second node N2. The third transistor T3 includes a gate electrode connected to a control scan line GCL, a source electrode connected to the second node N2, and a drain electrode connected to the first node N1. The control scan signal of the control scan line GCL can turn on the third transistor T3 to connect the first node N1 to the second node N2. Accordingly, the gate electrode and the drain electrode of the first transistor T1 may be connected, so that the first transistor T1 operates as a diode.

The fourth transistor T4 may be connected between the second node N2 and a third node N3. The fourth transistor T4 includes a gate electrode connected to the first emission control line EL1, a source electrode connected to the second node N2, and a drain electrode connected to the third node N3. The fourth transistor T4 may be turned on by the first emission control signal of the first emission control line EL1 to connect the second node N2 to the third node N3. Accordingly, the driving current of the first transistor T1 may be supplied to the light emitting element LE.

The fifth transistor T5 may be disposed between the third node N3 and the third driving voltage line VIL. The fifth transistor T5 includes a gate electrode connected to the bias scan line EBL, a source electrode connected to the third node N3, and a drain electrode connected to the third driving voltage line VIL. The fifth transistor T5 may be turned on by the bias scan signal of the bias scan line EBL to connect the third node N3 to the third driving voltage line VIL. Accordingly, the third driving voltage VINT of the third driving voltage line VIL may be applied to the first electrode of the light emitting element LE.

The sixth transistor T6 may be disposed between the source electrode of the first transistor T1 and the second driving voltage line VDL. The sixth transistor T6 includes a gate electrode connected to the second emission control line EL2, a source electrode connected to the second driving voltage line VDL, and a drain electrode connected to the source electrode of the first transistor T1. The sixth transistor T6 may be turned on by the second emission control signal of the second emission control line EL2 to connect the source electrode of the first transistor T1 to the second driving voltage line VDL. Accordingly, the second driving voltage VDD of the second driving voltage line VDL may be applied to the source electrode of the first transistor T1.

The first capacitor C1 is between the first node N1 and the drain electrode of the second transistor T2. The first capacitor C1 includes one electrode connected to the drain electrode of the second transistor T2 and another electrode connected to the first node N1.

The second capacitor C2 is between the gate electrode of the first transistor T1 and the second driving voltage line VDL. The second capacitor C2 includes one electrode connected to the gate electrode of the first transistor T1 and another electrode connected to the second driving voltage line VDL.

The first node N1 is the contact point of the gate electrode of the first transistor T1, the drain electrode of the third transistor T3, another electrode of the first capacitor C1, and one electrode of the second capacitor C2. The second node N2 is the contact point of the drain electrode of the first transistor T1, the source electrode of the third transistor T3, and the source electrode of the fourth transistor T4. The third node N3 is the contact point of the drain electrode of the fourth transistor T4, the source electrode of the fifth transistor T5, and the first electrode of the light emitting element LE.

Each of the first to sixth transistors T1 to T6 may be a metal-oxide-semiconductor field effect transistor (MOSFET). For example, each of the first to sixth transistors T1 to T6 may be a P-type MOSFET, but embodiments of the present disclosure are not limited thereto. For example, each of the first to sixth transistors T1 to T6 may be an N-type MOSFET. Alternatively, among the first to sixth transistors T1 to T6, some transistors may be P-type MOSFETs, and the other transistors may be N-type MOSFETs.

Although FIG. 7 shows the first sub-pixel SP1 as including six transistors T1 to T6 and two capacitors C1 and C2, the first sub-pixel SP1 is not limited to the equivalent circuit shown in FIG. 7. For example, the number of transistors and the number of capacitors of the first sub-pixel SP1 are not limited to those shown in FIG. 7.

Further, the equivalent circuit diagram of the second sub-pixel SP2 and the equivalent circuit diagram of the third sub-pixel SP3 may be substantially the same as the equivalent circuit diagram of the first sub-pixel SP1 described in conjunction with FIG. 7. Therefore, the description of the equivalent circuit diagram of the second sub-pixel SP2 and the equivalent circuit diagram of the third sub-pixel SP3 would be redundant and are omitted in the present disclosure.

FIG. 8 schematically illustrates a cross section of a part of a display panel according to one embodiment. For example, FIG. 8 is a diagram schematically illustrating a stacked structure suitable for each of the non-display area NDA and the display area DAA of the display panel 410 according to one embodiment.

In the description with reference to FIG. 8, the term “on” may refer to the third direction DR3 in which the front surface of the substrate SSUB faces. The front surface of the substrate SSUB may refer to a direction in which the light emitting element LE disposed in the display area DAA emits light for displaying an image.

Referring to FIG. 8, the display panel 410 according to one embodiment may include the substrate SSUB, and the substrate SSUB may be a semiconductor wafer substrate.

A driving element layer 801, at least one wiring layer 802, a light emitting element layer 803 including the light emitting element LE, an encapsulation layer 804 covering the light emitting element LE, a color filter layer 805 including a color filter CF, a light control layer 806 including a refractive layer MLA, and a cover layer 807 including a cover member CV may be sequentially stacked on the front surface of the substrate SSUB. At least some of the light emitting element layer 803, the encapsulation layer 804, the color filter layer 805, the light control layer 806, and the cover layer 807 may be in the display area DAA but may not be present in the non-display area NDA.

The substrate SSUB may be a silicon substrate, a germanium substrate, or a silicon-germanium substrate. The substrate SSUB may be a substrate doped with first type impurities. The first type impurities may be P-type impurities, and second type impurities may be N-type impurities. Alternatively, the first-type impurities may be N-type impurities, and the second-type impurities may be P-type impurities.

The driving element layer 801 including an N-type MOSFET and/or a P-type MOSFET is disposed on the substrate SSUB. The plurality of scan transistors of the scan driver 510 (see FIG. 6) may be disposed in the driving element layer 801. The plurality of emission control transistors of the emission driver 520 (see FIG. 6) may be disposed in the driving element layer 801. The plurality of pixel transistors T1 to T6 (see FIG. 7) described with reference to FIG. 7 may be disposed in the driving element layer 801. The plurality of data transistors of the data driver 530 (see FIG. 6) may be disposed in the driving element layer 801. The driving element layer 801 may thus include the scan transistors of the scan driver 510, the emission control transistors of the emission driver 520, the pixel transistors of the pixel circuit, and data transistors of the data driver 530.

For simplicity of description, FIG. 8 illustrates, as an example, any one MOSFET MOS among the plurality of pixel transistors T1 to T6 (see FIG. 7) disposed in the display area DAA of the display panel 410. Further, FIG. 8 illustrates, as an example, an N-type MOSFET MOS among the transistors included in the driving element layer 801.

The N-type MOSFET MOS may include a well region W1 doped with N-type impurities in the substrate SSUB doped with P-type impurities. The well region W1 may include a first low-concentration impurity region LDD1 and a second low-concentration impurity region LDD2 having a relatively lower impurity concentration than other portions. The first low-concentration impurity region LDD1 may define a source region S1, and the second low-concentration impurity region LDD2 may define a drain region D1. The source electrode SE of the MOSFET MOS may be connected to the source region S1, and the drain electrode DE of the MOSFET MOS may be connected to the drain region D1.

A channel CH disposed to overlap a gate G1 is between the first low-concentration impurity region LDD1 and the second low-concentration impurity region LDD2 in the well region W1. An insulating layer (not shown) that may be an oxide layer may be disposed between the gate G1 and the well region W1.

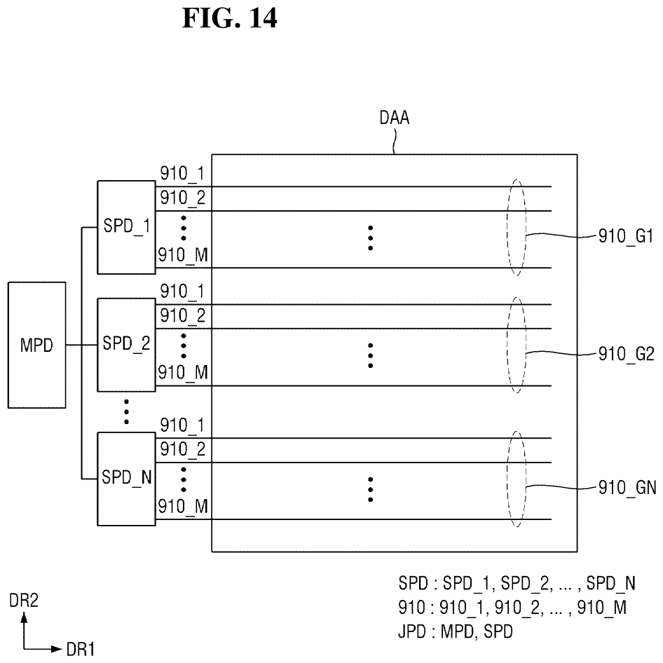

At least one wiring layer 802 is disposed on the driving element layer 801. The at least one wiring layer 802 includes insulating layers VIA sequentially stacked on the driving element layer 801, and a connection electrode CE and a line (not shown) connected to the MOSFET MOS through contact holes CT1 penetrating at least a part of the insulating layers VIA. That is, the wiring layers 802 include the connection electrode CE and connection lines that connect the MOSFETs MOS of the driving element layer 801 to each other, and the insulating layers VIA for insulating them from each other. Further, the wiring layers 802 may include a plurality of power lines 910 (see FIG. 14), and a plurality of signal lines for driving the display panel 410.

The connection electrode CE shown in FIG. 8 connects some MOSFETs MOS among the plurality of pixel transistors T1 to T6 (see FIG. 7) disposed in the driving element layer 801 to the light emitting element LE disposed on the wiring layer 802 in a vertical direction. Here, the vertical direction refers to the normal direction (that is the third direction) DR3 of the display panel 410.

The lines (not shown) disposed in the wiring layer 802 may include, for example, the lines GWL, GCL, EBL, EL1, EL2, VIL, VSL, and VDL (see FIG. 7) connected to the pixel driving circuit PC.

The wiring layer 802 may include pad electrodes PD1, PD2, PD3, PD4, PD5, PD6, and PD7 in the non-display area NDA. The pad electrodes PD1, PD2, PD3, PD4, PD5, PD6, and PD7 may include a first gate pad PD1 to which the write scan line GWL is connected, a second gate pad PD2 to which the control scan line GCL is connected, a third gate pad PD3 to which the bias scan line EBL is connected, a first emission control pad PD4 to which the first emission control line EL1 is connected, a second emission control pad PD5 to which the second emission control line EL2 is connected, a first driving voltage pad PD6 to which the first driving voltage line VSL is connected, and a second driving voltage pad PD7 to which the second driving voltage line VDL is connected. However, the pad electrodes PD1, PD2, PD3, PD4, PD5, PD6, and PD7 shown in FIG. 8 are merely examples, and the present disclosure is not limited thereto.

A planarization layer FL including an organic layer may be disposed on the uppermost layer among the insulating layers VIA included in the wiring layer 802, but the present disclosure is not limited thereto.

The light emitting element layer 803 including a pixel defining layer PDL delimiting the plurality of sub-pixels SP (see FIG. 6), and the light emitting element LE may be disposed on the wiring layer 802. The light emitting element LE includes a first electrode ANE connected to the MOSFET MOS included in the pixel driving circuit PC through a contact hole CT2 and the connection electrode CE, an intermediate layer ML disposed on the first electrode ANE, and a second electrode CAE disposed on the intermediate layer ML. The pixel defining layer PDL may include openings OP (see FIG. 9) respectively corresponding to the plurality of sub-pixels SP, and the first electrode ANE of the light emitting element LE may be exposed through each opening OP during processing.

The intermediate layer ML may include a hole injection layer, a hole transport layer, a light emitting layer, an electron transport layer, and an electron injection layer, but the present disclosure is not limited thereto. For example, the light emitting element LE may be an RGB type light emitting element in which a first color light (for example, red light) is emitted from the first sub-pixel SP1 (see FIG. 9) (for example, red pixel), a second color light (for example, green light) is emitted from the second sub-pixel SP2 (see FIG. 9) (for example, green pixel), and a third color light (for example, blue light) is emitted from the third sub-pixel SP3 (see FIG. 9) (for example, blue pixel). Alternatively, the light emitting element LE may be a WOLED type light emitting element in which white light is emitted from the first sub-pixel SP1 (for example, red pixel), the second sub-pixel SP2 (for example, green pixel), and the third sub-pixel SP3 (for example, blue pixel).

The stacked structure of organic materials included in the intermediate layer ML may include different structures depending on whether the light emitting element LE is an RGB type or a WOLED (white OLED) type, but the present disclosure is not limited thereto.

A heating line 810 is disposed on the pixel defining layer PDL, and the heating line 810 disconnects the intermediate layer ML of the light emitting elements LE between adjacent sub-pixels SP during processing. The disconnection of the middle layer ML occurs during a process of applying a Joule heating voltage to the heating line 810. The process of applying the Joule heating voltage to the heating line 810 may be performed after the intermediate layer ML is deposited.

In accordance with one embodiment, the heating line 810 is electrically connected to the power line 910 (see FIGS. 9 to 11) through a first connection electrode 821 disposed to vertically penetrate the pixel defining layer PDL. The heating line 810 is configured to receive the Joule heating voltage through the power line 910 and the first connection electrode 821 and generate heat based on the inputted joule heating voltage. The Joule heating voltage and resulting current causes the temperature of the heating line 810 to rise to a high temperature, e.g., about 400° C. or higher, and the intermediate layer ML deposited on and around the heating line 810 may be removed by the high temperature.

In one embodiment, it is possible to prevent leakage current between adjacent sub-pixels SP and the color crosstalk phenomenon by disconnecting the intermediate layer ML of the light emitting element LE between adjacent sub-pixels SP. The color crosstalk phenomenon refers to, for example, a phenomenon in which a red pixel (for example, the first sub-pixel SP1) adjacent to a blue pixel (for example, the third sub-pixel SP3) is unintentionally turned on while the blue pixel is emitting a blue color light. The color crosstalk phenomenon, which occurs due to a leakage current, may occur when a blue pixel and a red pixel that are adjacent to each other have a large difference in driving voltages. For example, the leakage current is a phenomenon in which a part of the driving current is transmitted to the red pixel (for example, the first sub-pixel SP1) through at least some conductive layers of the intermediate layer ML while the driving current is being supplied to the light emitting element LE of the blue pixel in order to turn on the blue pixel. If the leakage current occurs, the red pixel may be unintentionally turned on while the blue pixel is being turned on.

The encapsulation layer 804, which may include at least one organic encapsulation layer and at least one inorganic encapsulation layer, may be on the light emitting element layer 803. For example, the encapsulation layer 804 may include a first encapsulation inorganic layer TFE1, an encapsulation organic layer TFE2, and a second encapsulation inorganic layer TFE3, but the present disclosure is not limited thereto.

The color filter layer 805 including the color filter CF may be disposed on the encapsulation layer 804. The color filter CF may include a first color filter that transmits red light, a second color filter that transmits green light, and a third color filter that transmits blue light, but the present disclosure is not limited thereto. The color filter layer 805 may be provided when the light emitting element LE of the light emitting element layer 803 is a WOLED type light emitting element. If the light emitting element LE of the light emitting element layer 803 is an RGB type light emitting element LE that directly emits red light, green light, and blue light, the color filter layer 805 may be omitted.

The light control layer 806 including the refractive layer MLA is disposed on the color filter layer 805. The refractive layer MLA may refract light emitted from the light emitting element layer 803 toward the normal direction (that is the third direction DR3) of the display panel 410. The refractive layer MLA may include a micro lens array.

The cover layer 807 serving as the cover of the display panel 410 may be disposed on the light control layer 806. The cover layer 807 may include the cover member CV made of glass, but the present disclosure is not limited thereto. The cover layer 807 may include, for example, a protective film.

FIG. 9 is a cross-sectional diagram illustrating a power line disposed on the same layer as a reflective electrode according to one embodiment.

Referring to FIG. 9, a reflective electrode RL is on the insulating layers VIA included in the wiring layer 802 and is patterned to form regions corresponding to each of the sub-pixels SP1, SP2, and SP3. According to one embodiment, the reflective electrode RL may include a first reflective electrode RL1, a second reflective electrode RL2, and a third reflective electrode RL3 that are sequentially stacked on the insulating layers VIA.

The first reflective electrode RL1 may be formed of any one of copper (Cu), aluminum (Al), tungsten (W), molybdenum (Mo), chromium (Cr), gold (Au), titanium (Ti), nickel (Ni), and neodymium (Nd), or an alloy containing any one of them.

The second reflective electrode RL2 may be disposed on the first reflective electrode RL1. The second reflective electrode RL2 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them.

The third reflective electrode RL3 may be disposed on the second reflective electrode RL2. The third reflective electrode RL3 may include a metal having a high reflectance to facilitate reflection of light. The third reflective electrode RL3 may be formed of aluminum (Al), a stacked structure (Ti/Al/Ti) of aluminum and titanium, a stacked structure (ITO/Al/ITO) of aluminum and ITO, an APC alloy, which is an alloy of silver (Ag), palladium (Pd), and copper (Cu), and a stacked structure (ITO/APC/ITO) of the APC alloy and ITO, but the present disclosure is not limited thereto.

At least one of the first reflective electrode RL1, the second reflective electrode RL2, or the third reflective electrode RL3 may be omitted.

According to one embodiment, a power line 910 may be disposed to correspond to between the adjacent sub-pixels SP1, SP2, and SP3. The power line 910 may be disposed on the same layer as the reflective electrode RL. For example, the power line 910 and the reflective electrode RL may be formed of the same material through the same process.

According to one embodiment, a differential layer IL may be disposed on the reflective electrode RL. The differential layer IL may include a first differential layer IL1 and a second differential layer IL2 disposed on the first differential layer IL1. The differential layer IL may be commonly stacked in the first sub-pixel SP1 and the second sub-pixel SP2 but may not be stacked or present in the third sub-pixel SP3.

The differential layer IL may serve to vary distance between the first electrode ANE (see FIG. 8) and the reflective electrode RL for each of the first sub-pixel SP1, the second sub-pixel SP2, and the third sub-pixel SP3. In the first sub-pixel SP1, the first differential layer IL1, the second differential layer IL2, and the first electrode ANE1 of the first sub-pixel SP1 may be sequentially stacked on the reflective electrode RL. In the second sub-pixel SP2, the second differential layer IL2 and the first electrode ANE2 of the second sub-pixel SP2 may be sequentially stacked on the reflective electrode RL. In the third sub-pixel SP3, the first electrode ANE3 of the third sub-pixel SP3 may be disposed on the reflective electrode RL. Accordingly, the distance between the first electrode ANE and the reflective electrode RL may be different for each of the first sub-pixel SP1, the second sub-pixel SP2, and the third sub-pixel SP3. For example, the distance between the first electrode ANE and the reflective electrode RL may be longest in the first sub-pixel SP1 and shortest in the third sub-pixel SP3 due to the difference in thickness of the differential layer IL.

According to one embodiment, the pixel defining layer PDL that delimits the sub-pixels SP1, SP2, and SP3 is disposed on the first electrodes ANE1, ANE2, and ANE3 and the differential layer IL. The pixel defining layer PDL may cover both ends of each of the first electrodes ANE1, ANE2, and ANE3 of the respective sub-pixels SP1, SP2, and SP3. In the opening OP through the pixel defining layer PDL, each of the first electrodes ANE1, ANE2, and ANE3 is disposed to be partially exposed during processing.

A heating line 810 is disposed on the pixel defining layer PDL among the adjacent sub-pixels SP1, SP2, and SP3. The heating line 810 may surround each of the first electrodes ANE1, ANE2, and ANE3 of the respective sub-pixel SP1, SP2, and SP3. The heating line 810 may be electrically connected to the power line 910 via the first connection electrode 821. The first connection electrode 821 connects the heating line 810 to the power line 910 through a first contact hole CT821 penetrating the pixel defining layer PDL and a part of the wiring layer (e.g., the differential layer IL).

In the display panel 410 according to one embodiment, the heating line 810 is disposed in areas among the sub-pixels SP1, SP2, and SP3 to prevent a leakage current. When the heating line 810 disposed among the adjacent sub-pixels SP1, SP2, and SP3 is electrically driven, heat and a high temperature are generated. The generated high temperature disconnects at least some of the conductive layers included in the intermediate layer ML. According to the present disclosure, the leakage current and color interference may be prevented by disconnecting at least some of the conductive layers included in the intermediate layer ML around the heating line 810. In this disclosure, at least some conductive layers of the intermediate layer ML disconnected around the heating line 810 may include at least one of a hole injection layer, a hole transport layer, an electron transport layer, and an electron injection layer.

According to one embodiment, the intermediate layer ML of the light emitting element LE is disposed on the first electrodes ANE1, ANE2, and ANE3. The intermediate layer ML covers the first electrodes ANE1, ANE2, and ANE3 in the opening OP of the pixel defining layer PDL and covers the pixel defining layer PDL around the adjacent sub-pixels SP1, SP2, and SP3. However, while the intermediate layer ML covers the pixel defining layer PDL, the intermediate layer ML is partially disconnected above the heating line 810. Accordingly, the intermediate layer ML is disposed in common in sub-pixels SP1, SP2, and SP3, but the intermediate layer ML is partially disconnected above the heating line 810 disposed between the adjacent sub-pixels SP1, SP2, and SP3.

According to one embodiment, the second electrode CAE is disposed on the intermediate layer ML. The second electrode CAE may be disposed in common in the sub-pixels SP1, SP2, and SP3. The second electrode CAE may be a common layer in which the plurality of sub-pixels SP1, SP2, and SP3 are connected to each other. Specifically, the second electrode CAE may continuously cover the intermediate layer ML and the heating line 810 among the adjacent sub-pixels SP1, SP2, and SP3 while covering the intermediate layer ML in the opening OP of the pixel defining layer PDL.

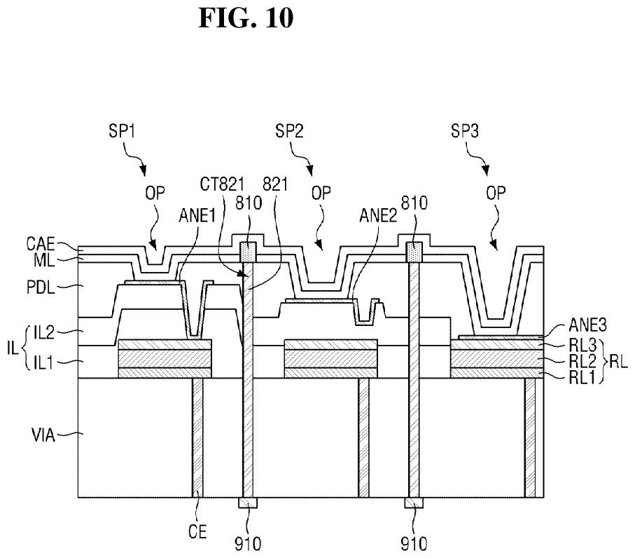

FIG. 10 is a cross-sectional diagram illustrating a power line in a wiring layer according to one embodiment.

The embodiment of FIG. 10 is different from the embodiment of FIG. 9 in that the power line 910 in the embodiment of FIG. 10 is disposed in the wiring layer 802. Hereinafter, a redundant description of the embodiment of FIG. 9 will be omitted in the description of the embodiment of FIG. 10, and only differences in the embodiment of FIG. 10 will be described.

Referring to FIG. 10, the power line 910 may be disposed on any one of the insulating layers VIA included in the wiring layer 802 (see FIG. 8). For example, the power line 910 may be disposed on the same layer as any one of the lines and the connection electrode CE described with reference to FIG. 8.

According to one embodiment, the power line 910 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them.

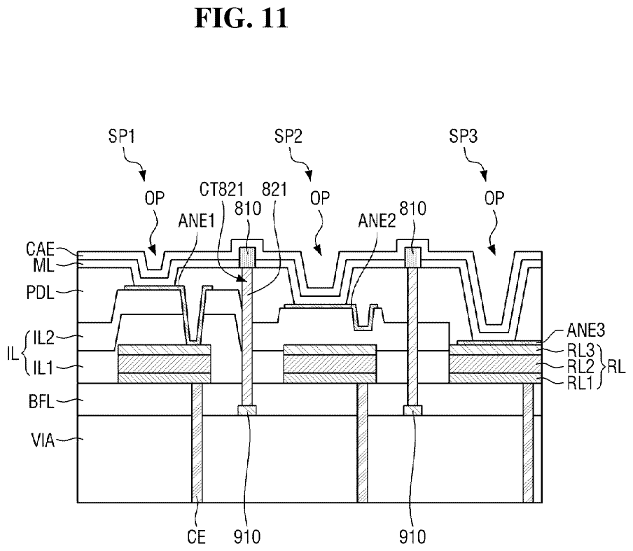

FIG. 11 is a diagram illustrating arrangement of a power line in a buffer layer according to one embodiment.

The embodiment of FIG. 11 is different from the embodiment of FIG. 9 in that the power line 910 in the embodiment of FIG. 11 is disposed in the buffer layer BFL. Hereinafter, a redundant description of the embodiment of FIG. 9 will be omitted in the description of the embodiment of FIG. 11, and only differences in the embodiment of FIG. 11 will be described.

Referring to FIG. 11, the display panel 410 may further include the buffer layer BFL between the wiring layer 802 and the reflective electrode RL. The power line 910 may be disposed in the buffer layer BFL. The buffer layer BFL may be formed of a silicon oxide (SiOₓ)-based inorganic layer, but the present disclosure is not limited thereto.

According to one embodiment, the power line 910 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them.

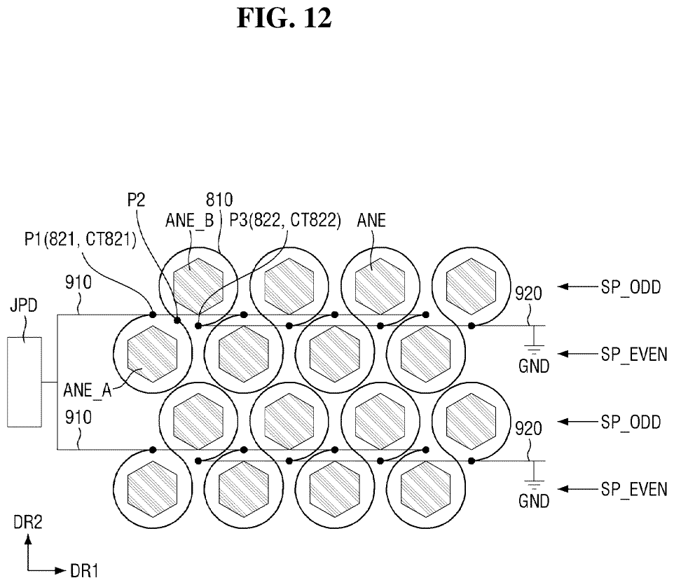

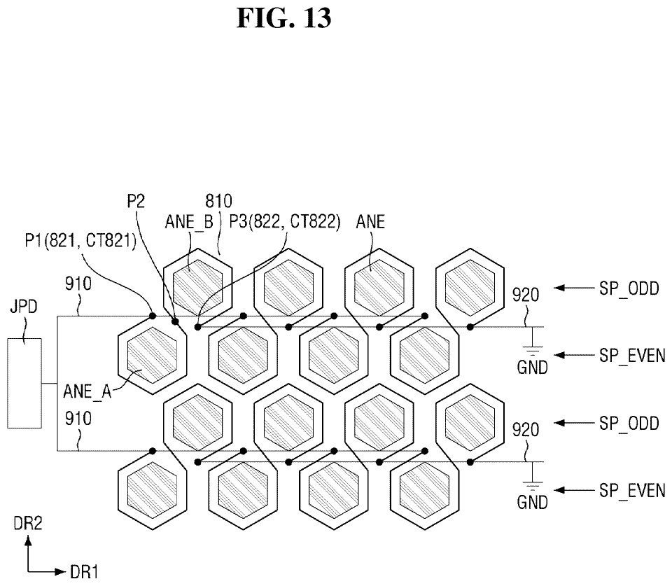

FIG. 12 is a plan view for describing an S-shaped pattern of heating lines according to one embodiment. FIG. 13 is a plan view illustrating heating lines in a hexagonal shaped pattern.

Referring to FIG. 12, each of the sub-pixels SP may include the first electrode ANE. The first electrode ANE of each sub-pixel SP may have a hexagonal structure having a hexagonal shape, in plan view, when viewed in the normal direction of the substrate SSUB (see FIG. 8).

According to one embodiment, each heating line 810 is disposed to surround a pair of first electrodes ANE_A and ANE_B, which correspond to the sub-pixels SP disposed adjacently, in the form of a Eulerian trail. The Eulerian trail form means a form of arranging a line so that once a line or a path is visited, it is not visited again. Therefore, each heating line 810 surrounding the pair of the adjacent first electrodes ANE_A and ANE_B is disposed to visit a start point P1, a midpoint P2, and an end point P3 only once. According to one embodiment, when viewed in the normal direction of the substrate SSUB, the heating line 810 may have a shape of the letter “S” as the heating line 810 extends from the start point P1 to the end point P3 via the midpoint P2.

In this disclosure, the start point P1, the midpoint P2, and the end point P3 are preferably understood as virtual points representing some points on each heating line 810. For example, the start point P1 may be a point where the heating line 810 is connected to the power line 910 and may be one end of the heating line 810. The end point P3 may be a point where the heating line 810 is connected to a ground line 920 and may be the other end of the heating line 810. The midpoint P2 may be a point that bisects the entire length of the heating line 810. A distance from the midpoint P2 to the start point P1 may be substantially equal to a distance from the midpoint P2 to the end point P3.

According to one embodiment, the wiring layer 802 includes the power line 910 and a ground line 920. The power line 910 and the ground line 920 may be disposed to cross between sub-pixels SP_ODD disposed in an odd row and sub-pixels SP_EVEN disposed in an even row. The start point P1 of the heating line 810 is connected to the power line 910 through the first connection electrode 821 disposed in the first contact hole CT821. The end point P3 of the heating line 810 is connected to the ground line 920 through the second connection electrode 822 disposed in the second contact hole CT822. Accordingly, the start point P1 and the end point P3 of each heating line 810 may be disposed between the sub-pixels SP_ODD disposed in the odd row and the sub-pixels SP_EVEN disposed in the even row.

According to one embodiment, the heating line 810 extends to surround a second reference sub-pixel (or the first electrode ANE_A of the second reference sub-pixel) among the sub-pixels SP_EVEN disposed in the even row from the start point P1 to be connected to the midpoint P2 that is adjacent to the start point P1. The heating line 810 extends from the midpoint P2 to surround a first reference sub-pixel (or the first electrode ANE_B of the first reference sub-pixel) adjacent to the second reference sub-pixel among the sub-pixels SP_ODD disposed in the odd row to be connected to the end point P3. In this case, the midpoint P2 of the heating line 810 is disposed between the start point P1 and the end point P3. Accordingly, when viewed in the normal direction of the substrate SSUB, the heating line 810 may have the shape of the letter “S” as heating line 810 extends from the start point P1 to the end point P3 via the midpoint P2.

In one embodiment of the present disclosure, each heating line 810 is disposed to surround the pair of the first electrodes ANE_A and ANE_B, which correspond to the sub-pixels SP disposed adjacently, in the Eulerian trail form. Accordingly, the length of each heating line 810 may be reduced. In addition, as the length of the heating line 810 is reduced, the Joule heating voltage may be lowered. For example, when the heating line 810 surrounds the plurality of sub-pixels SP in a mesh form, the resistance and length thereof increase. Thus, a Joule heating voltage of about 3300V may be required. On the other hand, in one embodiment of the present disclosure, each heating line 810 is driven with a Joule heating voltage of about 6V, and the intermediate layer ML may be disconnected using the driven heating line 810.

According to the illustrated example, each heating line 810 surrounds the periphery of the first electrode ANE in a circular shape, but the present disclosure is not limited thereto. For example, the shape in which each heating line 810 surrounds the first electrode ANE may depend on the structure or shape of the first electrode ANE. For example, the first electrode ANE of each sub-pixel SP may have an n-gonal shape (n is an integer greater than or equal to 4) when viewed in the normal direction of the substrate SSUB. The heating line 810 may have an n-gonal shape spaced apart from the first electrode ANE at a specific interval. Thus, when the first electrode ANE of each sub-pixel SP has a hexagonal structure, the heating line 810 may have a hexagonal shape spaced apart from the first electrode ANE at a specific interval, as shown in FIG. 13.

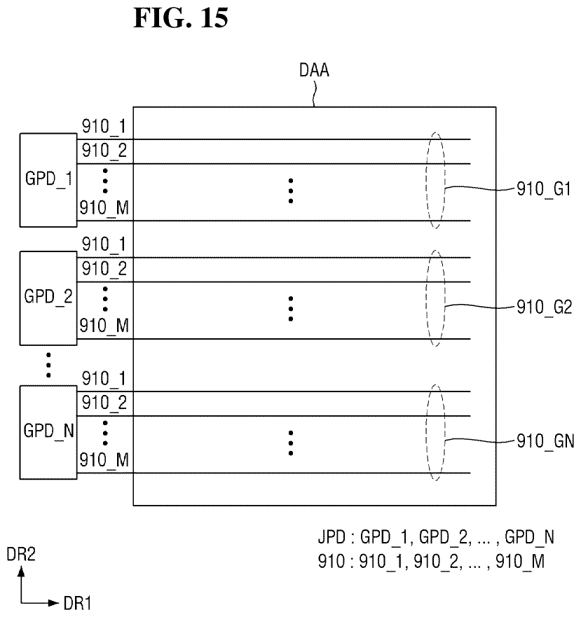

According to one embodiment, the power lines 910 may be connected to a power pad JPD disposed in the non-display area of the substrate SSUB. The power pad JPD may be divided into a plurality of parts without being provided as a single component in order to decrease a current when a Joule heating voltage is applied. Dividing the power pad JPD into the plurality of power pads according to one embodiment will be described below in detail with reference to FIGS. 14 and 15.

FIG. 14 is a plan view illustrating a power pad according to one embodiment.

Referring to FIG. 14, the power pad JPD according to one embodiment is disposed in the non-display area of the substrate SSUB, and a Joule heating voltage is applied to the power pad JPD. The power pad JPD is connected to the plurality of power lines 910 that extend to and in the display area, and thus the Joule heating voltage applied to the power pad JPD may be transmitted to the heating line 810 via the power lines 910.

The power pad JPD according to one embodiment may include a main pad MPD to which a Joule heating voltage is applied and sub-pads SPD branched from the main pad MPD.

The main pad MPD may be a pad to which a Joule heating voltage is applied and may be provided as a single component. The sub-pads SPD may be provided for each group of a plurality of the power lines 910. For example, as shown in the drawing, when the number of the power lines 910 is N*M in total (here, * is a multiplication sign, and each of N and M is an integer greater than 2), the lines 910 may be divided into N groups 910_G1 to 910_GN, each of which includes M power lines 910. In this case, the main pad MPD is provided as a single component, but the sub-pads SPD may include N sub-pads SPD_1 to SPD_N corresponding to the N groups 910_G1 to 910_GN. For example, the first sub-pad SPD_1 may receive a Joule heating voltage from the main pad MPD and may supply the received Joule heating voltage to the first to Mt power lines 910_1 to 910_M included in the first group 910_G1. Similarly, the second sub-pad SPD_2 may receive a Joule heating voltage from the main pad MPD and may supply the received Joule heating voltage to the first to M^{th} power lines 910_1 to 910_M included in the second group 910_G2.

In this embodiment of the present disclosure, a current may be decreased when a Joule heating voltage is supplied, by dividing the power pad JPD into the plurality of power pads.

Meanwhile, in the display panel 410 according to one embodiment, the power pad JPD may not be provided in the non-display area. For example, the power pad JPD may be a dummy pad that is not substantially used after the process of disconnecting the intermediate layer ML by supplying a Joule heating voltage to the heating line 810. Accordingly, after the process, a partial area of the substrate SSUB on which the power pad JPD is disposed may be removed by a cutting process of cutting the periphery of the display panel 410.

FIG. 15 is a plan view illustrating another shape of the power pad according to one embodiment.

The embodiment of FIG. 15 is different from the embodiment of FIG. 14 in that the power pad JPD is not divided into the main pad MPD and the sub-pad SPD.

Referring to FIG. 15, the power pad JPD may be provided for each of the groups 910_G1 to 910_GN of the power lines 910 without being divided into the main pad MPD to which a Joule heating voltage is applied and the sub-pads SPD branched therefrom. For example, as shown in the drawing, when the number of the power lines 910 is N*M in total (here, * is a multiplication sign, and each of N and M is an integer greater than 2), the power lines 910 may be divided into N groups 910_G1 to 910_GN, each of which includes M power lines 910. In this case, the power pad JPD may include group pads GPD_1 to GPD_N respectively provided for the groups 910_G1 to 910_GN.

Specifically, the power pad JPD may include N group pads GPD_1 to GPD_N corresponding to the N groups 910_G1 to 910_GN of the power lines 910. A Joule heating voltage may be directly applied to each of the group pads GPD_1 to GPD_N. For example, the first group pad GPD_1 may receive a Joule heating voltage and supply the received Joule heating voltage to the first to M^{th} power lines 910_1 to 910_M included in the first group 910_G1. Similarly, the second group pad GPD_2 may receive a Joule heating voltage independently from the first group pad GPD_1 and may supply the received Joule heating voltage to the first to M^{th} power lines 910_1 to 910_M included in the second group 910_G2.

Meanwhile, in the display panel 410 according to one embodiment, the power pad JPD may not be provided in the non-display area. For example, the power pad JPD is a dummy pad that is not substantially used after the process of disconnecting the intermediate layer ML by supplying the Joule heating voltage to the heating line 810. Accordingly, after the process, a partial area of the substrate SSUB on which the power pad JPD is disposed may be removed by a cutting process of cutting the periphery of the display panel 410.

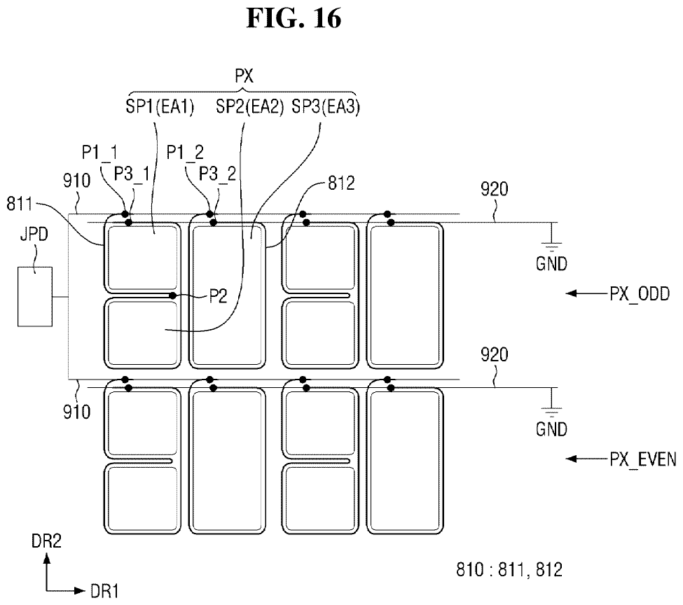

FIG. 16 is a plan view illustrating heating lines according to one embodiment.

The embodiment of FIG. 16 is different from the embodiment of FIG. 12 in that the heating line 810 in the embodiment of FIG. 16 is disposed to surround the periphery of the opening OP (see FIG. 9) of the sub-pixel SP (see FIG. 6) (i.e., the emission area of the sub-pixel SP). Hereinafter, a redundant description of the embodiment of FIG. 12 will be omitted in the description of the embodiment of FIG. 16, and only differences in the embodiment of FIG. 16 will be described.

Referring to FIG. 16, the display panel 410 according to one embodiment may include a plurality of pixels PX. The plurality of pixels PX may be arranged in a matrix form, and emission areas EA1, EA2, and EA3 may have a stripe structure.

According to one embodiment, each of the pixels PX may include the first sub-pixel SP1 displaying light of a first color, the second sub-pixel SP2 displaying light of a second color, and the third sub-pixel SP3 displaying light of a third color. Here, the light of the first color may be light of a red wavelength band, the light of the second color may be light of a green wavelength band, and the light of the third color may be light of a blue wavelength band. For example, the blue wavelength band may indicate that the main peak wavelength of light is included in a wavelength band of approximately 370 nm to 460 nm, the green wavelength band may indicate that the main peak wavelength of light is included in a wavelength band of approximately 480 nm to 560 nm, and the red wavelength band may indicate that the main peak wavelength of light is included in a wavelength band of approximately 600 nm to 750 nm.

According to one embodiment, each of the pixels PX includes the first emission area EA1 that is an emission area of the first sub-pixel SP1, the second emission area EA2 that is an emission area of the second sub-pixel SP2, and the third emission area EA3 that is an emission area of the third sub-pixel SP3. Each of the first emission area EA1, the second emission area EA2, and the third emission area EA3 may be substantially the same as the corresponding opening OP in the pixel defining layer PDL (see FIG. 9).

Each of the first emission area EA1, the second emission area EA2, and the third emission area EA3 may have a quadrangle shape such as a rectangle, a square, or a rhombus in plan view.

The first emission area EA1 and the second emission area EA2 may be disposed adjacent to each other in a column direction. Here, the column direction may be the second direction DR2 in which the data lines DL (see FIG. 6) extend.

The first emission area EA1 (or the second emission area EA2) and the third emission area EA3 may be disposed adjacent to each other in the row direction. Here, the row direction may be the first direction DR1 in which the scan lines SL (see FIG. 5) and the plurality of power lines 910 extend.

A third length of the third emission area EA3 in the column direction may be the same as or greater than the sum of a first length of the first emission area EA1 in the column direction and a second length of the second emission area EA2 in the column direction. For example, the size of the third emission area EA3 may be larger than the size of the first emission area EA1, and the size of the third emission area EA3 may be larger than the size of the second emission area EA2. For example, the size of the first emission area EA1 may be different from the size of the second emission area EA2.

According to one embodiment, the heating line 810 is disposed to surround a pair of openings OP in the pixel defining layer PDL, which correspond to the sub-pixels SP disposed adjacently, in the Eulerian trail form. The openings OP of the pixel defining layer PDL substantially indicate the emission areas EA1, EA2, EA3 of the corresponding sub-pixels SP. Accordingly, the heating line 810 may be disposed to surround a pair of emission areas (e.g., the emission areas EA1 and EA2), which correspond to the sub-pixels SP disposed adjacently, in the Eulerian trail form.

According to one embodiment, each heating line 810 is connected to the power line 910 and the ground line 920. For example, the start point P1 of the heating line 810 is connected to the power line 910 through the first connection electrode 821 (see FIG. 12), and the end point P3 of the heating line 810 is connected to the ground line 920 through the second connection electrode 822 (see FIG. 12). The first connection electrode 821 connects the start point P1 of the heating line 810 to the power line 910 through the first contact hole CT821 penetrating the pixel defining layer PDL and the wiring layer 802 (see FIG. 8). The second connection electrode 822 connects the end point P3 of the heating line 810 to the ground line 920 through the second contact hole CT822 penetrating the pixel defining layer PDL and the wiring layer 802.

According to one embodiment, the power line 910 and the ground line 920 are disposed to cross between the pixels PX_ODD disposed in the odd row and the pixels PX_EVEN disposed in the even row. For example, the power line 910 and the ground line 920 may extend parallel to the plurality of scan lines SL in the first direction DR1.

The heating line 810 may include a first heating line 811 and a second heating line 812 provided for each pixel PX. The first heating line 811 is disposed to surround the first emission area EA1 and the second emission area EA2 in the Eulerian trail form. The second heating line 812 is disposed to surround the third emission area EA3.

A first start point P1_1 and a first end point P3_1 of the first heating line 811 may be disposed between the second emission area EA2 of the pixels PX_ODD arranged in the odd row and the first emission area EA1 of the pixels PX_EVEN arranged in the even row. A second start point P1_2 and a second end point P3_2 of the second heating line 812 may be disposed between the third emission area EA3 of the pixels PX_ODD arranged in the odd row and the third emission area EA3 of the pixels PX_EVEN arranged in the even row.

The first heating line 811 may extend to surround the first emission area EA1 and the second emission area EA2, which are disposed adjacently, in the Eulerian trail form, as follows. For example, the first heating line 811 may extend from the first start point P1_1 to the midpoint P2 between the first emission area EA1 and the second emission area EA2 and may extent from the midpoint P2 to the first end point P3_1 while surrounding the periphery of the second emission area EA2. Here, the midpoint P2 may be disposed in the vicinity of the corner of the first emission area EA1, which is adjacent to the third emission area EA3.

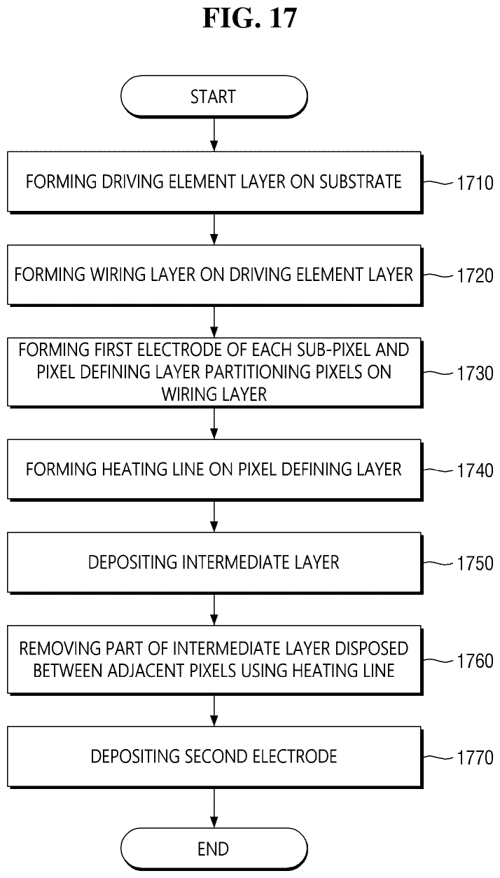

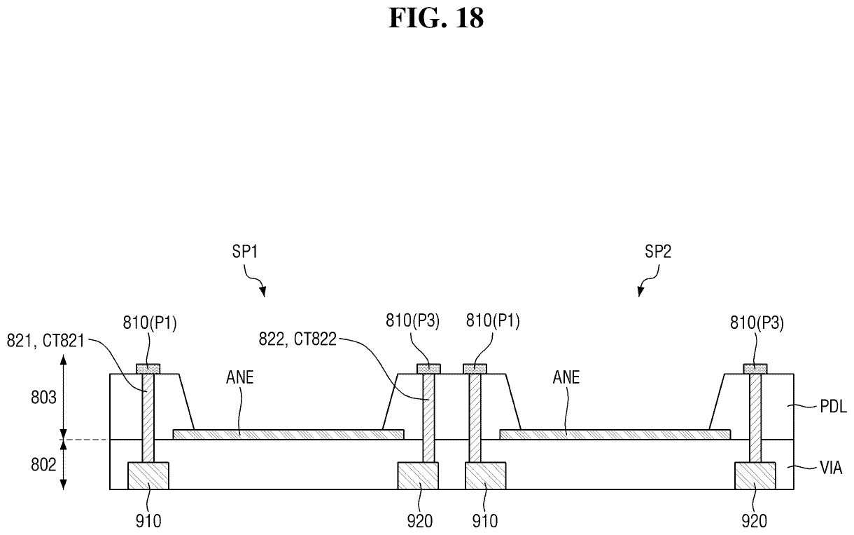

FIG. 17 is a flowchart illustrating a manufacturing method of a display panel according to one embodiment. FIGS. 18 to 21 are cross-sectional views sequentially illustrating the manufacturing method of the display panel according to one embodiment.

Hereinafter, the manufacturing method of the display panel 410 (see FIG. 4) according to one embodiment will be described with reference to FIGS. 17 to 21. The following description is only a part of the manufacturing processes of the display panel 410, and processes for forming components described with reference to this disclosure may be additionally performed before or after each step described below. Further, the manufacturing process of the display panel 410 known to those skilled in the art may be additionally performed before or after each step described below.

Referring to FIG. 17, in step 1710, the driving element layer 801 (see FIG. 8) may be formed on the substrate SSUB (see FIG. 8). The driving element layer 801 may include MOSFETs MOS described with reference to FIG. 8.

Referring to FIG. 17, in step 1720, the wiring layer 802 may be formed on the driving element layer 801. The wiring layer 802 may include insulating layers VIA that are sequentially stacked on the driving element layer 801, the connection electrode CE (see FIG. 8) penetrating at least a part of the insulating layers VIA, and a plurality of lines. According to one embodiment, the wiring layer 802 may further include the power line 910 to which a Joule heating voltage is applied and the ground line 920 connected to the ground. In the illustrated example, the power line 910 and the ground line 920 are disposed on the same layer, but the present disclosure is not limited thereto. For example, the power line 910 and the ground line 920 may be disposed on different layers.

Referring to FIG. 17, in step 1730, the first electrode ANE of each sub-pixel SP (see FIG. 6) and the pixel defining layer PDL delimiting the sub-pixels SP may be formed on the wiring layer 802. The first electrode ANE may be partially exposed through the opening OP (see FIG. 9) of the pixel defining layer PDL during processing. The edges of each first electrode ANE may be covered by the pixel defining layer PDL.

Referring to FIGS. 17 and 18, in step 1740, the first contact hole CT821 and the second contact hole CT822 penetrating the pixel defining layer PDL and at least a part of the insulating layers VIA are formed. Subsequently, the first connection electrode 821 connected to the power line 910 is formed by covering the first contact hole CT821. Further, the second connection electrode 822 connected to the ground line 920 is formed by covering the second contact hole CT822. Next, the heating line 810 is formed on the pixel defining layer PDL located between the adjacent sub-pixels (e.g., the sub-pixels SP1 and SP2).

According to one embodiment, as described with reference to FIGS. 12 and 13, the heating line 810 may be disposed to surround a pair of the first electrodes ANE_A and ANE_B, which correspond to the sub-pixels SP disposed adjacently, in the Eulerian trail form. The start point P1 of the heating line 810 is connected to the power line 910 through the first connection electrode 821 disposed in the first contact hole CT821. The end point P3 of the heating line 810 is connected to the ground line 920 through the second connection electrode 822 disposed in the second contact hole CT822.

According to one embodiment, as described with reference to FIG. 16, the heating line 810 may include the first heating line 811 surrounding the first emission area EA1 and the second emission area EA2 in the Eulerian trail form, and the second heating line 812 surrounding the third emission area EA3.

According to one embodiment, a first metal forming the heating line 810, a second metal forming the connection electrodes 821 and 822, and a third metal forming the power line 910 may be different from each other. The resistance of the first metal may be greater than the resistance of the second metal. The resistance of the second metal may be greater than the resistance of the third metal.

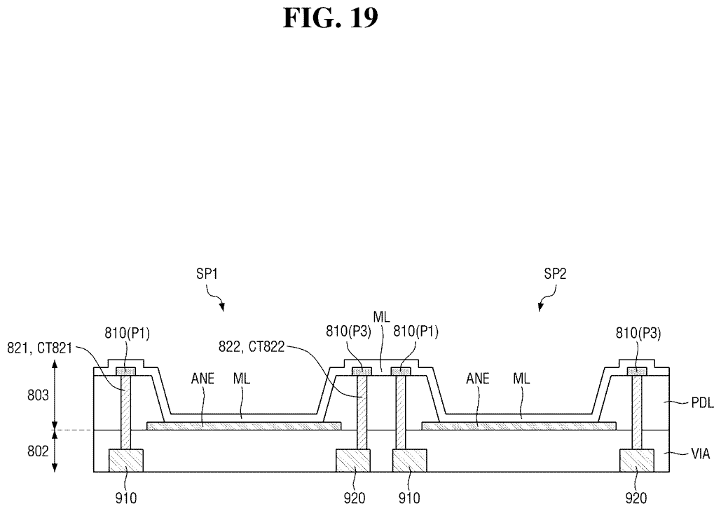

Referring to FIGS. 17 and 19, in step 1750, the intermediate layer ML may be deposited. For example, the intermediate layer ML may be disposed not only above the opening OP of the pixel defining layer PDL, but also on the pixel defining layer PDL disposed between the adjacent sub-pixels (e.g., the sub-pixels SP1 and SP2) using an open mask (not shown). Accordingly, the intermediate layer ML may cover the first electrode ANE and also cover the heating line 810 disposed on the pixel defining layer PDL in each opening OP of the pixel defining layer PDL.

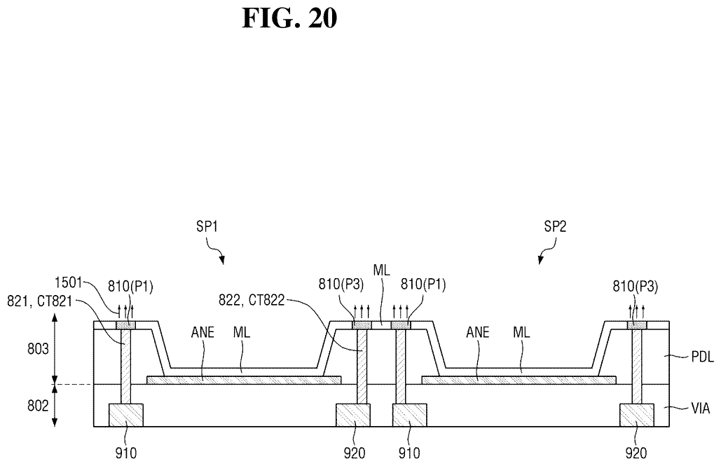

Referring to FIGS. 17 and 20, in step 1760, all or a part of the intermediate layer ML disposed between the adjacent sub-pixels (e.g., the sub-pixels SP1 and SP2) may be removed using the heating line 810. To this end, a Joule heating voltage is applied to the power pad JPD (see FIG. 12), and the Joule heating voltage applied to the power pad JPD may be transmitted to the heating line 810 via the power line 910. The heating line 810 is configured to receive the Joule heating voltage through the power line 910 and the first connection electrode 821 and generate heat 1501 based on the inputted Joule heating voltage. The temperature of the heating line 810 increases to a high temperature of about 400° C. or higher by the inputted Joule heating voltage, and the intermediate layer ML deposited on and around the heating line 810 may be removed due to the high temperature.

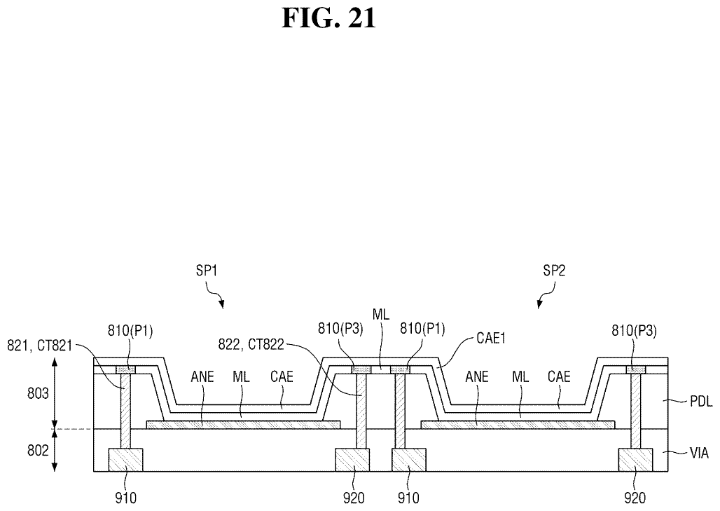

Referring to FIGS. 17 and 21, in step 1770, the second electrode CAE may be deposited. For example, the second electrode CAE may be disposed not only on the opening OP of the pixel defining layer PDL but also above the pixel defining layer PDL disposed between the adjacent sub-pixels (e.g., the sub-pixels SP1 and SP2) using an open mask. Accordingly, the second electrode CAE may cover the intermediate layer ML in each opening OP of the pixel defining layer PDL, and also cover the intermediate layer ML and the heating line 810 disposed on the pixel defining layer PDL.

In the manufacturing method of the display panel 410 described with reference to FIGS. 17 to 21, the process of removing all or a part of the intermediate layer ML using the heating line 810 is performed before the step of depositing the second electrode CAE, but the present disclosure is not limited thereto. For example, the process of removing a part of the intermediate layer ML using the heating line 810 may be performed after the step of depositing the second electrode CAE.

In concluding the detailed description, those skilled in the art will appreciate that many variations and modifications can be made to the example embodiments without substantially departing from the principles of the present disclosure. Therefore, the specific embodiments described herein are used in a generic and descriptive sense only and not for purposes of limitation.

What is claimed is:

1. A display device comprising:
a substrate;
a driving element layer disposed on the substrate; and
a light emitting element layer disposed on the driving element layer,
wherein the light emitting element layer comprises:
a pixel defining layer configured to delimit a plurality of sub-pixels;
a first electrode of each sub-pixel of the plurality of sub-pixels disposed in an opening of the pixel defining layer;
a heating line disposed on the pixel defining layer to surround the first electrode of each sub-pixel;
an intermediate layer configured to cover the first electrode in the opening and cover the pixel defining layer, and configured to be partially disconnected above the heating line; and
a second electrode disposed continuously to cover the intermediate layer and the heating line between adjacent sub-pixels while covering the intermediate layer in the opening,
wherein the heating line is disposed to surround a pair of first electrodes corresponding to the adjacent sub-pixels in a form of a Eulerian trail.

2. The display device of claim 1, wherein a wiring layer comprising a power line and a ground line is disposed between the driving element layer and the light emitting element layer, and
the power line and the ground line are disposed to cross between sub-pixels disposed in an odd row and sub-pixels disposed in an even row,
wherein the light emitting element layer further comprises:
a first connection electrode configured to connect a start point of the heating line to the power line through a first contact hole penetrating the pixel defining layer and at least a part of the wiring layer; and
a second connection electrode configured to connect an end point of the heating line to the ground line through a second contact hole penetrating the pixel defining layer and at least a part of the wiring layer.

3. The display device of claim 2, wherein the start point and the end point of the heating line are located between the sub-pixels disposed in the odd row and the sub-pixels disposed in the even row.

4. The display device of claim 3, wherein the heating line extends from the start point to surround a second reference sub-pixel among the sub-pixels disposed in the even row and is connected to a midpoint adjacent to the start point, and
the heating line extends from the midpoint to surround a first reference sub-pixel adjacent to the second reference sub-pixel among the sub-pixels disposed in the odd row and is connected to the end point.

5. The display device of claim 4, wherein the midpoint of the heating line is disposed between the start point and the end point.

6. The display device of claim 5, wherein when viewed in a normal direction of the substrate, the heating line has a shape of a letter S as the heating line extends from the start point to the end point via the midpoint.

7. The display device of claim 5, wherein the first electrode of each sub-pixel has an n-gonal shape when viewed in a normal direction of the substrate, wherein n is an integer greater than or equal to 4, and
the heating line has the n-gonal shape spaced apart from the first electrode at a specific interval when viewed in the normal direction of the substrate.

8. The display device of claim 7, wherein the first electrode of each sub-pixel has a hexagonal shape when viewed in the normal direction of the substrate, and
the heating line has the hexagonal shape spaced apart from the first electrode at the specific interval when viewed in the normal direction of the substrate.

9. The display device of claim 2, wherein the power line is connected to a power pad disposed in a non-display area of the substrate, and
the power pad comprises:
a main pad to which a Joule heating voltage is applied; and
sub-pads branched from the main pad and provided for each group obtained by evenly dividing a plurality of the power lines,
wherein the power lines comprised in each group receive the Joule heating voltage through the sub-pad.

10. The display device of claim 2, wherein the power line is connected to a power pad disposed in a non-display area of the substrate,
the power pad comprises group pads to which a Joule heating voltage is applied, and provided for each group obtained by evenly dividing a plurality of the power lines, and
the power lines comprised in each group receive the Joule heating voltage through the group pad.

11. A display device comprising:
a substrate;
a driving element layer disposed on the substrate; and
a light emitting element layer disposed on the driving element layer,
wherein the light emitting element layer comprises:
a pixel defining layer configured to delimit a plurality of sub-pixels;
a first electrode of each sub-pixel of the plurality of sub-pixels disposed in an opening of the pixel defining layer;
a heating line disposed on the pixel defining layer to surround the opening of each sub-pixel;
an intermediate layer configured to cover the first electrode in the opening and cover the pixel defining layer and configured to be partially disconnected above the heating line; and
a second electrode disposed continuously to cover the intermediate layer and the heating line between adjacent sub-pixels while covering the intermediate layer in the opening,
wherein the heating line is disposed to surround a pair of openings corresponding to the adjacent sub-pixels in a form of a Eulerian trail.

12. The display device of claim 11, wherein a wiring layer comprising a power line and a ground line is disposed between the driving element layer and the light emitting element layer, and
the power line and the ground line are disposed to cross between sub-pixels disposed in an odd row and sub-pixels disposed in an even row,
wherein the light emitting element layer further comprises:
a first connection electrode configured to connect a start point of the heating line to the power line through a first contact hole penetrating the pixel defining layer and at least a part of the wiring layer; and
a second connection electrode configured to connect an end point of the heating line to the ground line through a second contact hole penetrating the pixel defining layer and at least a part of the wiring layer.

13. The display device of claim 12, wherein one pixel comprises a first emission area of a first sub-pixel displaying red light, a second emission area of a second sub-pixel displaying green light, and a third emission area of a third sub-pixel displaying blue light,
the first emission area and the second emission area are disposed adjacent to each other in a column direction,
the first emission area and the third emission area are disposed adjacent to each other in a row direction, and
a third length of the third emission area in the column direction is greater than or equal to a sum of a first length of the first emission area in the column direction and a second length of the second emission area in the column direction.

14. The display device of claim 13, wherein the heating line comprises:
a first heating line disposed to surround the first emission area and the second emission area in the form of the Eulerian trail; and
a second heating line disposed to surround the third emission area.

15. The display device of claim 14, wherein a first start point and a first end point of the first heating line are disposed between the second emission area of a pixel disposed in the odd row and the first emission area of a pixel disposed in the even row, and
a second start point and a second end point of the second heating line are disposed between the third emission area of the pixel disposed in the odd row and the third emission area of the pixel disposed in the even row.

16. The display device of claim 15, wherein the first heating line extends from the first start point to a midpoint between the first emission area and the second emission area and extends from the midpoint to the first end point while surrounding a periphery of the second emission area.

17. The display device of claim 16, wherein the midpoint is disposed in a vicinity of a corner of the first emission area adjacent to the third emission area.

18. The display device of claim 13, wherein each of the first to third emission areas has a rectangular shape in plan view.

19. The display device of claim 12, wherein the power line is connected to a power pad disposed in a non-display area of the substrate, and
the power pad comprises:
a main pad to which a Joule heating voltage is applied; and
sub-pads branched from the main pad and provided for each group obtained by evenly dividing a plurality of the power lines,
wherein the power lines comprised in each group receive the Joule heating voltage through the sub-pad.

20. The display device of claim 12, wherein the power line is connected to a power pad disposed in a non-display area of the substrate,
the power pad comprises group pads to which a Joule heating voltage is applied, and provided for each group obtained by evenly dividing a plurality of the power lines, and
the power lines comprised in each group receive the Joule heating voltage through the group pad.
